(19) United States
(12) Patent Application Publication
(10) Pub. No.: US 2026/0305218 A1
(43) Pub. Date: Oct. 1, 2026

(54) METHOD FOR PROCESSING SEMICONDUCTOR SUBSTRATE

(71) Applicant: TOKYO OHKA KOGYO CO., LTD., Kanagawa (JP)

(72) Inventors: Eita SUGA, Kanagawa (JP); Yuan-Chia CHANG, Hsinchu City (TW); Tomoya KUMAGAI, Kanagawa (JP)

(21) Appl. No.: 19/576,022

(22) Filed: Mar. 24, 2026

(30) Foreign Application Priority Data
Mar. 27, 2025 (JP) 2025-052967

(51) Int. Cl. H10P 70/00; C08G 77/26; C08G 77/62; C09D 183/08; C09D 183/16

(52) U.S. Cl. CPC H10P 70/20; C08G 77/26; C08G 77/62; C09D 183/08; C09D 183/16

(57) ABSTRACT

Provided is a method for processing a semiconductor substrate, which method suppresses a change in the condition of the surface of the semiconductor substrate over a long period of time and additionally enables favorable processing of the semiconductor substrate without performing any particular treatment prior to the processing of the semiconductor substrate. The method for processing a semiconductor substrate includes: treating the surface of the semiconductor substrate by contacting the surface with a surface treatment liquid containing a silylating agent; drying the semiconductor substrate after the contact with the surface treatment liquid; and processing the semiconductor substrate after a lapse of 6 hours or more from the completion of the drying of the semiconductor substrate, in which a percentage change in water contact angle is 20% or less, in which the percentage change in the water contact angle is calculated from the contact angle CA1 of water on the surface of the semiconductor substrate before the contact with the surface treatment liquid and the contact angle CA2 of water on the surface of the semiconductor substrate at the time of the processing of the semiconductor substrate according to a predetermined equation.

### BACKGROUND OF THE INVENTION

### Field of the Invention

The present invention relates to a method for processing a semiconductor substrate.

### Related Art

Production of various semiconductor devices involves various types of processing on a semiconductor substrate. The outcomes of the processing on the semiconductor substrate often depend on the conditions of the surface of the semiconductor substrate to be processed.

In addition, trouble in a production line of semiconductor devices, or the like may cause a long waiting time before predetermined processing of the semiconductor substrate. In such a situation, the condition of the surface of the semiconductor substrate may undergo significant changes from its predetermined condition due to the influence of oxygen, moisture, various organic components, and the like in the air, or other various influences.

To address this problem, the application of a surface-protective composition containing a surface-protecting agent to the surface of the semiconductor substrate to form a surface-protecting layer, thereby preventing oxidation of the surface of the substrate has been proposed (see, for example, Patent Document 1).
Patent Document 1: PCT International Publication No. WO2023/182193

### SUMMARY OF THE INVENTION

However, in the method described in Patent Document 1, some types of surface-protecting agents lead to failure of the processing of the semiconductor substrate, or require the removal of the surface-protecting layer prior to the processing of the semiconductor substrate.

The present invention has been made in view of the circumstances described above, and an object of the present invention is to provide a method for processing a semiconductor substrate, which method suppresses a change in the condition of the surface of the semiconductor substrate over a long period of time and additionally enables favorable processing of the semiconductor substrate without performing any particular treatment prior to the processing of the same.

The present inventors have investigated a method for processing a semiconductor substrate, the method including: treating the surface of a semiconductor substrate by contacting the surface with a surface treatment liquid containing a silylating agent; drying the semiconductor substrate after the contact with the surface treatment liquid; and processing the semiconductor substrate after a lapse of 6 hours or more from the completion of the drying of the semiconductor substrate, and found that, in such a method, the above-mentioned problems can be solved by achieving a percentage change in water contact angle of 20% or less, in which the percentage change in the water contact angle is calculated from the contact angle CA1 of water on the surface of the semiconductor substrate before the contact with the surface treatment liquid and the contact angle CA2 of water on the surface of the semiconductor substrate at the time of the processing of the semiconductor substrate according to a predetermined equation, to accomplish the present invention. More specifically, the present invention provides the following.

An aspect of the invention relates to a method for processing a semiconductor substrate, the method including:
treating the surface of a semiconductor substrate by contacting the surface with a surface treatment liquid containing a silylating agent; drying the semiconductor substrate after the contact with the surface treatment liquid; and
processing the semiconductor substrate after a lapse of 6 hours or more from the completion of the drying of the semiconductor substrate, in which
a percentage change in water contact angle is 20% or less, in which the percentage change in the water contact angle is calculated from a contact angle CA1 of water on the surface of the semiconductor substrate before the contact with the surface treatment liquid and a contact angle CA2 of water on the surface of the semiconductor substrate at the time of the processing of the semiconductor substrate according to the following equation:

percentage change in water contact angle (%)=|(CA1−CA2)|/CA1×100

According to the present invention, it is possible to provide a method for processing a semiconductor substrate, which method suppresses a change in the condition of the surface of the semiconductor substrate over a long period of time and additionally enables favorable processing of the semiconductor substrate without performing any particular treatment prior to the processing of the same.

### DETAILED DESCRIPTION OF THE INVENTION

### <<Method for Processing Semiconductor Substrate>>

A method for processing a semiconductor substrate includes: treating the surface of a semiconductor substrate by contacting the surface with a surface treatment liquid containing a silylating agent; drying the semiconductor substrate after the contact with the surface treatment liquid; and processing the semiconductor substrate after a lapse of 6 hours or more from the completion of the drying of the semiconductor substrate. In the above-mentioned method for processing a semiconductor substrate, a percentage change in water contact angle is 20% or less, in which the percentage change in the water contact angle is calculated from the contact angle CA1 of water on the surface of the semiconductor substrate before the contact with the surface treatment liquid and the contact angle CA2 of water on the surface of the semiconductor substrate at the time of the processing of the semiconductor substrate according to the following equation:

percentage change in water contact angle (%)=|(CA1−CA2)|/CA1×100

The surface of the semiconductor substrate may be pre-treated prior to the treatment with the surface treatment liquid. Examples of a treatment agent for pretreating the surface of a semiconductor substrate (hereinafter, which may be referred to as “pretreatment agent”) include: peroxides such as hydrogen peroxide; perhalic acid such as periodic acid; oxo acids such as nitric acid and hypochlorous acid; phosphoric acid, citric acid, acetic acid, and hydrofluoric acid (HF); and the like. Hydrogen peroxide, an aqueous HF solution, or the like is preferably used as the pretreatment agent in light of its ability to remove native oxides and impurity removal. A single type of pretreatment agent may be used alone, and two or more types of pretreatment agent may be used in combination. Note that the substrate is preferably dried after the pretreatment with the pretreatment agent.

Specific examples of the pretreatment include cleaning. Examples of the cleaning method include SC1 cleaning with ammonia-hydrogen peroxide mixture (APM), which is prepared by diluting aqueous hydrogen peroxide and aqueous ammonia with ultra pure water, and cleaning with dilute hydrofluoric acid (dHF). The SC1 cleaning and the dHF cleaning may be performed in combination. In this case, the SC1 cleaning may precede the dHF cleaning, or vice versa. It is preferred that the dHF cleaning precedes the SC1 cleaning, from the viewpoint of generation of a large amount of hydroxyl groups on the surface of the substrate after the cleaning, and more favorable exhibition of the effect of the surface treatment with a silylating agent.

Hereinafter, the treating of a surface of a semiconductor substrate by contacting the surface with a surface treatment liquid containing a silylating agent is also referred to as a surface treatment step. The drying of the semiconductor substrate after the contact with the surface treatment liquid is also referred to as a drying step. The processing of the semiconductor substrate after a lapse of 6 hours or more from the completion of the drying of the semiconductor substrate is also referred to as a semiconductor substrate processing step.

Hereinafter, the surface treatment step, the drying step, and the semiconductor substrate processing step will be each described.

### <Surface Treatment Step>

In the surface treatment step, the surface of a semiconductor substrate is treated by contacting the surface with a surface treatment liquid containing a silylating agent.

### [Semiconductor Substrate]

The semiconductor substrate is not limited and any substrate used for manufacturing a semiconductor device may be used. A silicon substrate is typically used as the semiconductor substrate. Various functional layers, patterned organic films, patterned inorganic films, and the like may be formed on the surface of the silicon substrate.

The material of the surface of the semiconductor substrate is preferably a silicon-containing material. Examples of the silicon-containing material include one or more selected from silicon (Si), silicon oxide (SiO₂), silicon nitride (SiN), silicon oxycarbide (SiOC), silicon oxycarbonitride (SiOCN), and polysilicon (Poly-Si).

### [Surface Treatment Liquid]

The surface treatment liquid contains a silylating agent and a solvent. The solvent is not limited and any solvent which solubilizes the silylating agent and is less likely to react rapidly with the silylating agent may be used. Typically, an organic solvent is used as the solvent.

### [Silylating Agent]

The silylating agent is not limited. Any silylating agent conventionally used for the purpose of hydrophobizing the surface of various articles can be used as the silylating agent without particular limitation. Examples of a suitable silylating agent include silylating agents represented by the following formulas (1) to (8) and cyclic silazane compounds. Among the following silylating agents, a silylating agent represented by the formula (1) and/or a silylating agent represented by the formula (2) are preferred.

### (Silylating Agent Represented by Formula (1))

(R¹)₃Si—N(R²)(R³) (1)

In the formula (1), R¹ is a hydrogen atom, a halogen atom, or an organic group. A plurality of R¹s may be the same as or different from each other. The sum of the number of carbon atoms in three R¹s is 1 or more. R² is a hydrogen atom or a chain hydrocarbon group. R³ is a hydrogen atom, a chain hydrocarbon group, or a non-aromatic cyclic group. R² and R³ may be bonded to each other to form a ring.

In the formula (1), R¹ is a hydrogen atom, a halogen atom, or an organic group. Examples of the halogen atom include a chlorine atom, a bromine atom, an iodine atom, and a fluorine atom. The organic group may include a heteroatom such as a nitrogen atom, an oxygen atom, and a sulfur atom in addition to the carbon atom(s).

In three R¹s, the sum of the number of carbon atoms and the number of heteroatoms is not limited so long as the sum of the number of carbon atoms in the three R¹s is 1 or more. In the three R¹s, the sum of the number of carbon atoms and the number of heteroatoms is preferably 1 or more and 10 or less, more preferably 1 or more and 8 or less, and still more preferably 1 or more and 3 or less.

The organic group is preferably a saturated or unsaturated chain hydrocarbon group, an aralkyl group, and an aromatic hydrocarbon group. Suitable examples of the saturated or unsaturated chain hydrocarbon group include a methyl group, an ethyl group, a vinyl group, an n-propyl group, an isopropyl group, an allyl group, a 1-propenyl group, an isopropenyl group, an n-butyl group, a sec-butyl group, a tert-butyl group, a 3-butenyl group, an n-pentyl group, an isopentyl group, a sec-pentyl group, a tert-pentyl group, an n-hexyl group, an n-heptyl group, an n-octyl group, an n-nonyl group, and an n-decyl group. Among these saturated or unsaturated chain hydrocarbon groups, a methyl group, an ethyl group, a vinyl group, an n-propyl group, and an allyl group are preferred, and a methyl group, an ethyl group, and a vinyl group are more preferred. Suitable examples of the aralkyl group include a benzyl group, a phenylethyl group, a phenylpropyl group, an α-naphthylmethyl group, and a β-naphthylmethyl group. Suitable examples of the aromatic hydrocarbon group include a phenyl group, an α-naphthyl group, and a β-naphthyl group.

In the formula (1), R² is a hydrogen atom or a chain hydrocarbon group. The number of carbon atoms of the chain hydrocarbon group is not limited. The number of carbon atoms of the chain hydrocarbon group is preferably 1 or more and 10 or less, more preferably 1 or more and 8 or less, and still more preferably 1 or more and 3 or less. The chain hydrocarbon group is a saturated or unsaturated chain hydrocarbon group. Suitable examples of the saturated or unsaturated chain hydrocarbon group are the same as those listed for the saturated or unsaturated chain hydrocarbon group in the organic group as described above.

In the formula (1), R³ is a hydrogen atom, a chain hydrocarbon group, or a non-aromatic cyclic group. Examples of the chain hydrocarbon group are the same as those listed for the chain hydrocarbon group as described above.

Examples of the non-aromatic cyclic group include a saturated or unsaturated non-aromatic cyclic hydrocarbon group, and a non-aromatic heterocyclic group. The number of carbon atoms of the saturated or unsaturated non-aromatic cyclic hydrocarbon group is not limited. The number of carbon atoms of the saturated or unsaturated non-aromatic cyclic hydrocarbon group is preferably 3 or more and 10 or less, more preferably 3 or more and 6 or less, and still more preferably 5 or 6. Suitable examples of the saturated or unsaturated non-aromatic cyclic hydrocarbon group include a cyclopropyl group, a cyclobutyl group, a cyclopentyl group, a cyclohexyl group, a cyclopentyl group, and a cyclooctyl group.

The heteroatom included in the non-aromatic heterocyclic group is not limited. Examples of the heteroatom included in the non-aromatic heterocyclic group include a nitrogen atom, an oxygen atom, and a sulfur atom. The sum of the number of carbon atoms included in the non-aromatic heterocyclic group and the number of heteroatoms included therein is not limited. The sum of the number of carbon atoms included in the non-aromatic heterocyclic group and the number of heteroatoms included therein is preferably 3 or more and 10 or less, more preferably 3 or more and 6 or less, and still more preferably 5 or 6. Suitable examples of the non-aromatic heterocyclic group include a pyrrolidin-1-yl group, a piperidin-1-yl group, a piperazin-1-yl group, a morpholin-1-yl group, and a thiomorpholin-1-yl group.

In the formula (1), R² and R³ may be bonded to each other to form a ring. The number of atoms included in the ring structure formed by R² and R³ bonded to each other is not limited so long as the ring structure can be formed. The ring structure formed by R² and R³ bonded to each other is preferably a 3- to 10-membered ring, and more preferably a 5- or 6-membered ring. The ring structure formed by R² and R³ bonded to each other may include a heteroatom other than a nitrogen atom, such as an oxygen atom and a sulfur atom. Suitable examples of the ring structure formed by R² and R³ bonded to each other include: non-aromatic heterocyclic rings such as pyrrolidine, piperidine, piperazine, morpholine, and thiomorpholine; and aromatic heterocyclic rings such as imidazole and triazole.

Specific examples of the silylating agent represented by the formula (1) include N,N-dimethylaminotrimethylsilane (TMSDMA), N,N-dimethylaminodimethylsilane, N,N-dimethylaminomonomethylsilane, N,N-diethylaminotrimethylsilane, tert-butylaminotrimethylsilane, allylaminotrimethylsilane, trimethylsilylacetamide, N,N-dimethylaminodimethylvinylsilane, N,N-dimethylaminodimethylpropylsilane, N,N-dimethylaminodimethyloctylsilane, N,N-dimethylaminodimethylphenylethylsilane, N,N-dimethylaminodimethylphenylsilane, N,N-dimethylaminodimethyl-tert-butylsilane, N,N-dimethylaminotriethylsilane, trimethylsilanamine, monomethylsilylimidazole, dimethylsilylimidazole, trimethylsilylimidazole, monomethylsilyltriazole, dimethylsilyltriazole, trimethylsilyltriazole, and the like.

### (Silylating Agent Represented by Formula (2))

(R¹)₃Si—N(R⁴)—Si(R⁵)₃ (2)

In the formula (2), R¹ is the same as R¹ in the formula (1). R⁴ is a hydrogen atom, a methyl group, a trimethylsilyl group, or a dimethylsilyl group. R⁵ is a hydrogen atom or an organic group, and a plurality of R⁵s may be the same as or different from each other. The sum of the number of carbon atoms in the three R⁵s is 1 or more.

Specific examples of the silylating agent represented by the formula (2) include hexamethyldisilazane (HMDS), N-methylhexamethyldisilazane, 1,1,3,3-tetramethyldisilazane, 1,3-dimethyldisilazane, 1,3-di-n-octyl-1,1,3,3-tetramethyldisilazane, 1,3-divinyl-1,1,3,3-tetramethyldisilazane, tris(dimethylsilyl)amine, tris(trimethylsilyl)amine, 1-ethyl-1,1,3,3,3-pentamethyldisilazane, 1-vinyl-1,1,3,3,3-pentamethyldisilazane, 1-propyl-1,1,3,3,3-pentamethyldisilazane, 1-phenylethyl-1,1,3,3,3-pentamethyldisilazane, 1-tert-butyl-1,1,3,3,3-pentamethyldisilazane, 1-phenyl-1,1,3,3,3-pentamethyldisilazane, 1,1,1-trimethyl-3,3,3-triethyldisilazane, and the like.

### (Silylating Agent Represented by Formula (3))

(R¹)₃Si—O—C(═Y)(R⁶) (3)

In the formula (3), R¹ is the same as R¹ in the formula (1). Y is O, CHR⁷, CHOR⁷, C(R⁷)₂, or NR⁷. R⁷ is a hydrogen atom, a saturated or unsaturated chain hydrocarbon group, a saturated or unsaturated non-aromatic cyclic hydrocarbon group, a trialkylsilyl group, a trialkylsiloxy group, an alkoxy group, a phenyl group, a phenylethyl group, or an acetyl group, and a plurality of R⁷s may be the same as or different from each other. R⁶ is a hydrogen atom, an alkyl group, or a trialkylsilyl group.

The saturated or unsaturated chain hydrocarbon group is the same as the saturated or unsaturated chain hydrocarbon group for the organic group in the formula (1). The saturated or unsaturated non-aromatic cyclic hydrocarbon group is the same as the saturated or unsaturated non-aromatic cyclic hydrocarbon group for the non-aromatic cyclic group in the formula (1).

The number of carbon atoms of the respective alkyl groups included in the trialkylsilyl group, the trialkylsiloxy group, and the alkoxy group is not limited. The number of carbon atoms of the alkyl groups included in these groups is preferably 1 or more and 10 or less, more preferably 1 or more and 8 or less, and still more preferably 1 or more and 3 or less. Suitable examples of the alkyl group included in these groups include a methyl group, an ethyl group, an n-propyl group, an isopropyl group, an n-butyl group, a sec-butyl group, a tert-butyl group, an n-pentyl group, an isopentyl group, a sec-pentyl group, a tert-pentyl group, an n-hexyl group, an n-heptyl group, an n-octyl group, an n-nonyl group, an n-decyl group, and the like. Among these alkyl groups, a methyl group, an ethyl group, and an n-propyl group are more preferred, and a methyl group and an ethyl group are still more preferred.

The number of carbon atoms of the alkyl group is not limited. The number of carbon atoms of the alkyl group is preferably 1 or more and 10 or less, more preferably 1 or more and 8 or less, and still more preferably 1 or more and 3 or less. Suitable examples of the alkyl group include a methyl group, an ethyl group, an n-propyl group, an isopropyl group, an n-butyl group, a sec-butyl group, a tert-butyl group, an n-pentyl group, an isopentyl group, a sec-pentyl group, a tert-pentyl group, an n-hexyl group, an n-heptyl group, an n-octyl group, an n-nonyl group, an n-decyl group, and the like. Among these alkyl groups, a methyl group, an ethyl group, and an n-propyl group are more preferred, and a methyl group and an ethyl group are still more preferred.

Specific examples of the silylating agent represented by the formula (3) include trimethylsilyl acetate, dimethylsilyl acetate, monomethylsilyl acetate, trimethylsilyl propionate, trimethylsilyl butyrate, trimethylsilyl 2-butenoate, and the like.

### (Silylating Agent Represented by Formula (4))

(R¹)₃Si—N(R⁴)—C(═O)(R⁸) (4)

In the formula (4), R¹ is the same as R¹ in the formula (1). R⁴ is the same as R⁴ in the formula (2). R⁸ is a hydrogen atom, a saturated or unsaturated chain hydrocarbon group, a trifluoromethyl group, or a trialkylsilylamino group.

The saturated or unsaturated chain hydrocarbon group is the same as the saturated or unsaturated chain hydrocarbon group for the organic group in the formula (1).

The alkyl group included in the trialkylsilylamino group is the same as the alkyl group included in the trialkylsilyl group, the trialkylsiloxy group, and the alkoxy group in the formula (3).

Specific examples of the silylating agent represented by the formula (4) include an N,N′-bis(trimethylsilyl) urea, N-trimethylsilylacetamide, N-methyl-N-trimethylsilyltrifluoroacetamide, N,N-bis(trimethylsilyl)trifluoroacetamide, and the like.

### (Silylating Agent Represented by Formula (5))

(R⁹)—O—C(R¹⁰)═CH—C(═O)(R¹⁰) (5)

In the formula (5), R⁹ is a trialkylsilyl group. R¹⁰ is a hydrogen atom or an organic group, and a plurality of R¹⁰s may be the same as or different from each other.

The alkyl group included in the trialkylsilyl group is the same as the alkyl group included in the trialkylsilyl group, the trialkylsiloxy group, and the alkoxy group in the formula (3).

The organic group is the same as the organic group in the formula (1).

Specific examples of the silylating agent represented by the formula (5) include 2-trimethylsiloxypentan-2-en-4-one, and the like.

### (Silylating Agent Represented by Formula (6))

(R¹)₃Si—(R¹¹)(—R¹²)ₚ (6)

In the formula (6), R¹ is the same as R¹ in the formula (1). R¹¹ is a saturated or unsaturated chain hydrocarbon group, a saturated or unsaturated non-aromatic cyclic hydrocarbon group, or a non-aromatic heterocyclic group.

p is 0 or 1. When p is 1, R¹² is Si(R¹)₃, and Si in R¹² is bonded to R¹¹. R¹ in R¹² is the same as R¹ in the formula (1). When p is 0, the saturated or unsaturated chain hydrocarbon group is the same as the saturated or unsaturated chain hydrocarbon group for the organic group in the formula (1), and the saturated or unsaturated non-aromatic cyclic hydrocarbon group and the non-aromatic heterocyclic group are the same as the saturated or unsaturated non-aromatic cyclic hydrocarbon group and the non-aromatic heterocyclic group for the non-aromatic cyclic group in the formula (1). When p is 1, the saturated or unsaturated chain hydrocarbon group, the saturated or unsaturated non-aromatic cyclic hydrocarbon group, and the non-aromatic heterocyclic group are divalent groups derived from monovalent groups represented by the saturated or unsaturated chain hydrocarbon group, the saturated or unsaturated non-aromatic cyclic hydrocarbon group, and the non-aromatic heterocyclic group in the case of p being 0, respectively, by removal of one hydrogen atom.

Specific examples of the silylating agent represented by the formula (6) include 1,2-bis(dimethylchlorosilyl) ethane, tert-butyldimethylchlorosilane, and the like.

### (Silylating Agent Represented by Formula (7))

R¹³_{q}Si[N(CH₃)₂]_{4-q} (7)

In the formula (7), R¹³ is a chain hydrocarbon group having 1 or more and 18 or less carbon atoms, in which a part or all of the hydrogen atoms thereof are optionally substituted with a fluorine atom, and a plurality of R¹³s may be the same as or different from each other.

q is 1 or 2.

In R¹³, the number of carbon atoms is preferably 2 or more and 18 or less, and more preferably 8 or more and 18 or less. Examples of the chain hydrocarbon group include saturated chain hydrocarbon groups and unsaturated chain hydrocarbon groups.

Examples of the chain saturated hydrocarbon group not substituted with a fluorine atom include a methyl group, an ethyl group, an n-propyl group, an isopropyl group, a butyl group, a sec-butyl group, a tert-butyl group, an isobutyl group, an amyl group, an isoamyl group, a tert-amyl group, a hexyl group, a 2-hexyl group, a 3-hexyl group, a heptyl group, a 2-heptyl group, a 3-heptyl group, an isoheptyl group, a tert-heptyl group, an n-octyl group, an isooctyl group, a tert-octyl group, a 2-ethylhexyl group, a nonyl group, an isononyl group, a decyl group, a dodecyl group, a tridecyl group, a tetradecyl group, a pentadecyl group, a hexadecyl group, a heptadecyl group, an octadecyl group, and the like.

Examples of the chain unsaturated hydrocarbon group not substituted with a fluorine atom include a vinyl group, a 1-propenyl group, an allyl group, an isopropenyl group, a 1-butenyl group, a 2-butenyl group, a 3-butenyl group, a 1,3-butadienyl group, a 1-ethylvinyl group, a 1-methyl-1-propenyl group, a 1-methyl-2-propenyl group, a 4-pentenyl group, a 1,3-pentadienyl group, a 2,4-pentadienyl group, a 3-methyl-1-butenyl group, a 5-hexenyl group, a 2,4-hexadienyl group, a 6-heptenyl group, a 7-octenyl group, an 8-nonenyl group, a 9-decenyl group, a 10-undecenyl group, a 11-dodecenyl group, a 12-tridecenyl group, a 13-tetradecenyl group, a 14-pentadecenyl group, a 15-hexadecenyl group, a 16-heptadecenyl group, a 17-octadecenyl group, an ethynyl group, a propargyl group, a 1-propynyl group, a 1-butynyl group, a 2-butynyl group, a 3-butynyl group, a 1-pentynyl group, a 2-pentynyl group, a 3-pentynyl group, a 4-pentynyl group, a 1-hexynyl group, a 2-hexynyl group, a 3-hexynyl group, a 4-hexynyl group, a 5-hexynyl group, a 6-heptynyl group, a 7-octynyl group, an 8-nonynyl group, a 9-decynyl group, a 10-undecynyl group, an 11-dodecynyl group, a 12-tridecynyl group, a 13-tetradecynyl group, a 14-pentadecynyl group, a 15-hexadecynyl group, a 16-heptadecynyl group, a 17-octadecynyl group, and the like.

In the chain hydrocarbon group in which a part or all of the hydrogen atoms thereof is substituted with a fluorine atom, the number of substituting fluorine atoms and the position at which the substitution by the fluorine atom occurs are not limited. In the chain hydrocarbon group in which a part of hydrogen atoms thereof is substituted with a fluorine atom, the number of substituting fluorine atoms is preferably 50% or more, more preferably 70% or more, and still more preferably 80% or more of the number of hydrogen atoms included in the chain hydrocarbon group.

R¹³ is preferably a linear hydrocarbon group having 1 or more and 18 or less carbon atoms in which a part or all of the hydrogen atoms thereof are optionally substituted with a fluorine atom, from the viewpoint of easy exhibition of excellent hydrophobization effect. In addition, from the viewpoint of storage stability of the silylating agent, R¹³ is more preferably a linear saturated hydrocarbon group having 1 or more and 18 or less carbon atoms (alkyl group having 1 or more and 18 or less carbon atoms) in which a part or all of the hydrogen atoms thereof are optionally substituted with a fluorine atom.

q is 1 or 2, and preferably 1.

### (Silylating Agent Represented by Formula (8))

R¹⁴ᵣ[N(CH₃)₂]₃₋ᵣSi—R¹⁵—SiR¹⁴ₛ[N(CH₃)₂]₃₋ₛ (8)

In the formula (8), R¹⁴ is a hydrogen atom or a linear or branched alkyl group having 1 or more and 4 or less carbon atoms, and a plurality of R¹⁴s may be the same as or different from each other. R¹⁵ is a linear or branched alkylene group having 1 or more and 16 or less carbon atoms.
r and s are each independently an integer of 0 or more and 2 or less.

Examples of the linear or branched alkyl group having 1 or more and 4 or less carbon atoms include a methyl group, an ethyl group, an n-propyl group, an isopropyl group, an n-butyl group, a sec-butyl group, a tert-butyl group, an isobutyl group, and the like.

R¹⁴ is preferably a hydrogen atom, or a linear or branched alkyl group having 1 or more and 3 or less carbon atoms, more preferably a hydrogen atom, or a methyl group, and still more preferably a methyl group.

The number of carbon atoms of the linear or branched alkylene group is preferably 1 or more and 10 or less, and more preferably 2 or more and 8 or less. The linear alkylene group is a methylene group, or an α, ω-linear alkylene group. The branched alkylene group is an alkylene group other than a methylene group and an α, ω-linear alkylene group. R¹⁵ is preferably a linear alkylene group.

Examples of the linear or branched alkylene group having 1 or more and 16 or less carbon atoms include a methylene group, a 1,2-ethylene group, a 1,1-ethylene group, a propane-1,3-diyl group, a propane-1,2-diyl group, a propane-1,1-diyl group, a propane-2,2-diyl group, a butane-1,4-diyl group, a butane-1,3-diyl group, a butane-1,2-diyl group, a butane-1,1-diyl group, a butane-2,2-diyl group, a butane-2,3-diyl group, a pentane-1,5-diyl group, a pentane-1,4-diyl group, a hexane-1,6-diyl group, a heptane-1,7-diyl group, an octane-1,8-diyl group, a 2-ethylhexane-1,6-diyl group, a nonane-1,9-diyl group, a decane-1,10-diyl group, a undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and the like.

s and r are each independently an integer of 0 or more and 2 or less.

s and r are preferably 1 or 2, and more preferably 2 in light of ease in synthesis and high availability.

### (Cyclic Silazane Compound)

Examples of the cyclic silazane compound include: cyclic disilazane compounds such as 2,2,5,5-tetramethyl-2,5-disila-1-azacyclopentane and 2,2,6,6-tetramethyl-2,6-disila-1-azacyclohexane; cyclic trisilazane compounds such as 2,2,4,4,6,6-hexamethylcyclotrisilazane and 2,4,6-trimethyl-2,4,6-trivinylcyclotrisilazane; cyclic tetrasilazane compounds such as 2,2,4,4,6,6,8,8-octamethylcyclotetrasilazane; and the like.

Among these, a cyclic disilazane compound is preferred, and 2,2,5,5-tetramethyl-2,5-disila-1-azacyclopentane and 2,2,6,6-tetramethyl-2,6-disila-1-azacyclohexane are more preferred. Examples of the cyclic disilazane compound include those having 5-membered ring structures such as 2,2,5,5-tetramethyl-2,5-disila-1-azacyclopentane, and those having 6-membered ring structures such as 2,2,6,6-tetramethyl-2,6-disila-1-azacyclohexane, and a cyclic disilazane compound having a 5-membered ring structure is more preferred.

With regard to the silylating agents described above, a single type of silylating agent may be used alone, and two or more types of silylating agent may be used in combination.

The proportion of the mass of the silylating agent to the mass of the surface treatment liquid is preferably 1.00% by mass or more and 20.00% by mass or less, more preferably 2.00% by mass or more and 15.00% by mass or less, and still more preferably 3.00% by mass or more and 13.00% by mass or less.

### [Solvent]

The surface treatment liquid contains a solvent. An organic solvent is preferred as the solvent, as described above. Specific examples of the organic solvent include: sulfoxides such as dimethyl sulfoxide; sulfones such as dimethyl sulfone, diethyl sulfone, bis(2-hydroxyethyl) sulfone, and tetramethylene sulfone; amides such as N,N-dimethylformamide, N-methylformamide, N,N-dimethylacetamide, N-methylacetamide, and N,N-diethylacetamide; imidazolidinones such as 1,3-dimethyl-2-imidazolidinone, 1,3-diethyl-2-imidazolidinone, and 1,3-diisopropyl-2-imidazolidinone; dialkyl glycol ethers such as dimethyl glycol, dimethyl diglycol, dimethyl triglycol, methyl ethyl diglycol, diethyl glycol, and triethylene glycol butyl methyl ether; monohydric alcohol-based solvents such as methanol, ethanol, n-propanol, isopropanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxy butanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, methylisobutylcarbinol, phenol, cyclohexanol, methylcyclohexanol, 3,3,5-trimethylcyclohexanol, benzyl alcohol, phenylmethylcarbinol, diacetone alcohol, and cresol; (poly)alkylene glycol monoalkyl ethers such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether (PGME), propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, and tripropylene glycol monoethyl ether; (poly)alkylene glycol monoalkyl ether acetates such as ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, propylene glycol monomethyl ether acetate (PGMEA), and propylene glycol monoethyl ether acetate; other ethers such as dimethyl ether, diethyl ether, methyl ethyl ether, dipropyl ether, diisopropyl ether, dibutyl ether, diisoamyl ether, diethylene glycol dimethyl ether, diethylene glycol methyl ethyl ether, diethylene glycol monobutyl ether, diethylene glycol diethyl ether, tetraethylene glycol dimethyl ether, and tetrahydrofuran; ketones such as methyl ethyl ketone, cyclohexanone, 2-heptanone, and 3-heptanone; lactic acid alkyl esters such as methyl 2-hydroxypropionate and ethyl 2-hydroxypropionate; other esters such as ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanoate, 3-methoxybutyl acetate, 3-methyl-3-methoxy-1-butyl acetate, 3-methyl-3-methoxybutyl propionate, ethyl acetate, n-propyl acetate, i-propyl acetate, n-butyl acetate, i-butyl acetate, n-pentyl acetate, n-hexyl acetate, n-heptyl acetate, n-octyl acetate, n-pentyl formate, i-pentyl acetate, n-butyl propionate, ethyl butyrate, n-propyl butyrate, i-propyl butyrate, n-butyl butyrate, methyl n-octanoate, methyl decanoate, methyl pyruvate, ethyl pyruvate, n-propyl pyruvate, methyl acetoacetate, ethyl acetoacetate, ethyl 2-oxobutanoate, dimethyl adipate, and propylene glycol diacetate; lactones such as β-propiolactone, γ-butyrolactone, and 8-pentyrolactone; linear, branched, or cyclic aliphatic hydrocarbons such as n-hexane, n-heptane, n-octane, n-nonane, methyloctane, n-decane, n-undecane, n-dodecane, 2,2,4,6,6-pentamethylheptane, 2,2,4,4,6,8,8-heptamethylnonane, cyclohexane, and methylcyclohexane; aromatic hydrocarbons such as benzene, toluene, benzotrifluoride, xylene, 1,3,5-trimethylbenzene, naphthalene, and decahydronaphthalene; terpenes such as p-menthane, diphenylmenthane, limonene, terpinene, bornane, norbornane, and pinane; amines such as diisopropylamine, ethylenediamine, and diethylenetriamine; and the like. These solvents may be used either individually, or as a mixture of two or more types thereof.

### [Nitrogen-Containing Heterocyclic Compound]

The surface treatment liquid may contain a silicon atom-free nitrogen-containing heterocyclic compound (hereinafter, simply referred to as “nitrogen-containing heterocyclic compound”). The nitrogen-containing heterocyclic compound accelerates a silylation reaction by a silylating agent. When the surface treatment liquid containing the nitrogen-containing heterocyclic compound is used, the time for the surface treatment of a substrate can be further reduced.

The nitrogen-containing heterocyclic compound is not limited so long as it is silicon atom-free and contains a nitrogen atom in its ring structure. The nitrogen-containing heterocyclic compound may contain a heteroatom other than the nitrogen atom, such as an oxygen atom and a sulfur atom, in its ring structure. From the viewpoint of further increasing the hydrophobicity of the surface of a surface-treated substrate, the nitrogen-containing heterocyclic compound is preferably a nitrogen-containing heterocyclic ring with aromaticity.

The nitrogen-containing heterocyclic compound may be a compound in which two or more rings are bonded to each other via a single bond or a polyvalent linking group having two or more valences. In this case, the two or more rings bonded by the linking group are required to include at least one nitrogen-containing heterocyclic ring. Among polyvalent linking groups for linking the two or more rings, a divalent linking group is preferred in light of low steric hindrance between the rings. Specific examples of the divalent linking group include an alkylene group having 1 or more and 6 or less carbon atoms, —CO—, —CS—, —O—, —S—, —NH—, —N═N—, —CO—O—, —CO—NH—, —CO—S—, —CS—O—, —CS—S—, —CO—NH—CO—, —NH—CO—NH—, —SO—, —SO₂—, and the like. The number of rings included in the compound in which the two or more rings are bonded to each other via the polyvalent linking group is preferably 4 or less, more preferably 3 or less, and still more preferably 2 in light of easy preparation of a homogeneous surface treatment liquid. It should be noted that by way of example, the number of rings in a fused ring like a naphthalene ring is 2.

The nitrogen-containing heterocyclic compound may be a compound in which a plurality of rings are fused. In this case, at least one of the rings constituting the fused ring is required to be the nitrogen-containing heterocyclic ring. The number of rings included in the nitrogen-containing heterocyclic compound that has a plurality of rings fused is preferably 4 or less, more preferably 3 or less, and still more preferably 2 in light of easy preparation of a homogeneous surface treatment liquid.

The nitrogen-containing heterocyclic compound preferably has a 5-membered nitrogen-containing ring or a fused polycyclic ring including a 5-membered nitrogen-containing ring skeleton in light of favorable effects of the surface treatment with the surface treatment liquid.

Suitable examples of the nitrogen-containing heterocyclic compound include pyridine, pyridazine, pyrazine, pyrimidine, triazine, tetrazine, pyrrole, pyrazole, imidazole, triazole, tetrazole, oxazole, isoxazole, thiazole, isothiazole, oxadiazole, thiadiazole, quinoline, isoquinoline, cinnoline, phthalazine, quinoxaline, quinazoline, indole, indazole, benzimidazole, benzotriazole, benzoxazole, benzisoxazole, benzothiazole, benzisothiazole, benzoxadiazole, benzothiadiazole, saccharin, pyrrolidine, and piperidine. Among these, pyrrole, pyrazole, imidazole, triazole, tetrazole, oxazole, isoxazole, thiazole, isothiazole, oxadiazole, thiadiazole, indole, indazole, benzimidazole, benzotriazole, benzoxazole, benzisoxazole, benzothiazole, benzisothiazole, benzo oxadiazole, benzothiadiazole, and saccharin are preferred, and imidazole, triazole, tetrazole, benzotriazole, and pyrazole are more preferred. The nitrogen-containing heterocyclic compound having a substituent is also preferably used.

Examples of the substituent optionally included in the nitrogen-containing heterocyclic compound include an alkyl group having 1 or more and 6 or less carbon atoms, a cycloalkyl group having 3 or more and 8 or less carbon atoms, an alkoxy group having 1 or more and 6 or less carbon atoms, a cycloalkyloxy group having 3 or more and 8 or less carbon atoms, an aryl group having 6 or more and 20 or less carbon atoms, an aralkyl group having 7 or more and 20 or less carbon atoms, a halogenated alkyl group having 1 or more and 6 or less carbon atoms, an aliphatic acyl group having 2 or more and 7 or less carbon atoms, a halogenated aliphatic acyl group having 2 or more and 7 or less carbon atoms, an arylcarbonyl group having 7 or more and 20 or less carbon atoms, a carboxyalkyl group having 2 or more and 7 or less carbon atoms, a halogen atom, a mercapto group, an alkylthio group having 1 or more and 6 or less carbon atoms, an amino group, a monoalkylamino group having an alkyl group having 1 or more and 6 or less carbon atoms, a dialkylamino group having an alkyl group having 1 or more and 6 or less carbon atoms, a nitro group, a cyano group, and the like. The nitrogen-containing heterocyclic compound may have a plurality of substituents on the nitrogen-containing heterocyclic ring. When the number of substituents is 2 or more, the plurality of substituents may be the same as or different from each other. When these substituents include an aliphatic hydrocarbon ring, an aromatic hydrocarbon ring, or the like, these rings may further have the same substituent as the substituent which may be included in the nitrogen-containing heterocyclic compound.

The number of carbon atoms of the alkyl group as the substituent is 1 or more and 6 or less, preferably 1 or more and 4 or less, and more preferably 1 or 2. Specific examples of the alkyl group having 1 or more and 6 or less carbon atoms include a methyl group, an ethyl group, an n-propyl group, an isopropyl group, an n-butyl group, an isobutyl group, a sec-butyl group, a tert-butyl group, an n-pentyl group, and an n-hexyl group. Among these, a methyl group and an ethyl group are preferred, and a methyl group is more preferred.

The number of carbon atoms of the cycloalkyl group as the substituent is 3 or more and 8 or less, preferably 3 or more and 7 or less, and more preferably 4 or more and 6 or less. Specific examples of the cycloalkyl group having 3 or more and 8 or less carbon atoms include a cyclopropyl group, a cyclobutyl group, a cyclopentyl group, a cyclohexyl group, a cycloheptyl group, and a cyclooctyl group.

The number of carbon atoms of the alkoxy group as the substituent is 1 or more and 6 or less, preferably 1 or more and 4 or less, and more preferably 1 or 2. Specific examples of the alkoxy group having 1 or more and 6 or less carbon atoms include a methoxy group, an ethoxy group, an n-propyloxy group, an isopropyloxy group, an n-butyloxy group, an isobutyloxy group, a sec-butyloxy group, a tert-butyloxy group, an n-pentyloxy group, and an n-hexyloxy group. Among these, a methoxy group and an ethoxy group are preferred, and a methoxy group is more preferred.

The number of carbon atoms of the cycloalkyloxy group as the substituent is 3 or more and 8 or less, preferably 3 or more and 7 or less, and more preferably 4 or more and 6 or less. Specific examples of the cycloalkyloxy group having 3 or more and 8 or less carbon atoms include a cyclopropyloxy group, a cyclobutyloxy group, a cyclopentyloxy group, a cyclohexyloxy group, a cycloheptyloxy group, and a cyclooctyloxy group.

The number of carbon atoms of the aryl group as the substituent is 6 or more and 20 or less, and preferably 6 or more and 12 or less. Specific examples of the aryl group having 6 or more and 20 or less carbon atoms include a phenyl group, an α-naphthyl group, a β-naphthyl group, a biphenyl-4-yl group, a biphenyl-3-yl group, a biphenyl-2-yl group, an anthracen-1-yl group, an anthracen-2-yl group, an anthracen-9-yl group, a phenanthren-1-yl group, a phenanthren-2-yl group, a phenanthren-3-yl group, a phenanthren-4-yl group, and a phenanthren-9-yl group. Among these, a phenyl group, an α-naphthyl group, a β-naphthyl group, a biphenyl-4-yl group, a biphenyl-3-yl group, and a biphenyl-2-yl group are preferred, and a phenyl group is more preferred.

The number of carbon atoms of the aralkyl group as the substituent is 7 or more and 20 or less, and preferably 7 or more and 12 or less. Specific examples of the aralkyl group having 7 or more and 20 or less carbon atoms include a benzyl group, a phenethyl group, a 3-phenyl-n-propyl group, a 4-phenyl-n-butyl group, an α-naphthylmethyl group, a β-naphthylmethyl group, a 2-(α-naphthyl)ethyl group, and a 2-(β-naphthyl)ethyl group. Among these groups, a benzyl group and a phenethyl group are preferred, and a benzyl group is more preferred.

Examples of the halogen atom included in the halogenated alkyl group as the substituent include a fluorine atom, a chlorine atom, a bromine atom, and an iodine atom. The number of carbon atoms of the halogenated alkyl group as the substituent is 1 or more and 6 or less, preferably 1 or more and 4 or less, and more preferably 1 or 2. Specific examples of the halogenated alkyl group having 1 or more and 6 or less carbon atoms include a chloromethyl group, a dichloromethyl group, a trichloromethyl group, a fluoromethyl group, a difluoromethyl group, a trifluoromethyl group, a 1,1-difluoroethyl group, a 2,2,2-trifluoroethyl group, and a pentafluoroethyl group.

The number of carbon atoms of the aliphatic acyl group as the substituent is 2 or more and 7 or less, preferably 2 or more and 5 or less, and more preferably 2 or 3. Specific examples of the aliphatic acyl group having 2 or more and 7 or less carbon atoms include an acetyl group, a propionyl group, a butanoyl group, a pentanoyl group, a hexanoyl group, and a heptanoyl group. Among these, an acetyl group and a propanoyl group are preferred, and an acetyl group is more preferred.

Examples of the halogen atom included in the halogenated aliphatic acyl group as the substituent include a fluorine atom, a chlorine atom, a bromine atom, and an iodine atom. The number of carbon atoms of the halogenated aliphatic acyl group as the substituent is 2 or more and 7 or less, preferably 2 or more and 5 or less, and more preferably 1 or 2. Specific examples of the halogenated aliphatic acyl group having 2 or more and 7 or less carbon atoms include a chloroacetyl group, a dichloroacetyl group, a trichloroacetyl group, a fluoroacetyl group, a difluoroacetyl group, a trifluoroacetyl group, and a pentafluoropropionyl group.

The number of carbon atoms of the arylcarbonyl group as the substituent is 7 or more and 20 or less, and preferably 7 or more and 13 or less. Specific examples of the arylcarbonyl group having 7 or more and 20 or less carbon atoms include a benzoyl group, an α-naphthoyl group, and a β-naphthoyl group.

The number of carbon atoms of the carboxyalkyl group as the substituent is 2 or more and 7 or less, preferably 2 or more and 5 or less, and more preferably 2 or 3. Specific examples of the carboxyalkyl group having 2 or more and 7 or less carbon atoms include a carboxymethyl group, a 2-carboxyethyl group, a 3-carboxy-n-propyl group, a 4-carboxy-n-butyl group, a 5-carboxy-n-pentyl group, and a 6-carboxy-n-hexyl group. Among these, a carboxymethyl group is preferred.

Examples of the halogen atom include a fluorine atom, a chlorine atom, a bromine atom, and an iodine atom. Among these, a fluorine atom, a chlorine atom, and a bromine atom are preferred, and a chlorine atom and a bromine atom are more preferred.

The number of carbon atoms of the alkylthio group as the substituent is 1 or more and 6 or less, preferably 1 or more and 4 or less, and more preferably 1 or 2. Specific examples of the alkylthio group having 1 or more and 6 or less carbon atoms include a methylthio group, an ethylthio group, an n-propylthio group, an isopropylthio group, an n-butylthio group, an isobutylthio group, a sec-butylthio group, a tert-butylthio group, an n-pentylthio group, and an n-hexylthio group. Among these, a methylthio group and an ethylthio group are preferred, and a methylthio group is more preferred.

Specific examples of the alkyl group included in the monoalkylamino group having an alkyl group having 1 or more and 6 or less carbon atoms and the dialkylamino group having an alkyl group having 1 or more and 6 or less carbon atoms are the same as those of the above-mentioned alkyl group as the substituent. As the monoalkylamino group having an alkyl group having 1 or more and 6 or less carbon atoms, an ethylamino group and a methylamino group are preferred, and a methylamino group is more preferred. As dialkylamino group having an alkyl group having 1 or more and 6 or less carbon atoms, a diethylamino group and a dimethylamino group are preferred, and a dimethylamino group is more preferred.

Particularly suitable specific examples of the nitrogen-containing heterocyclic compound include compounds represented by the following formulas.

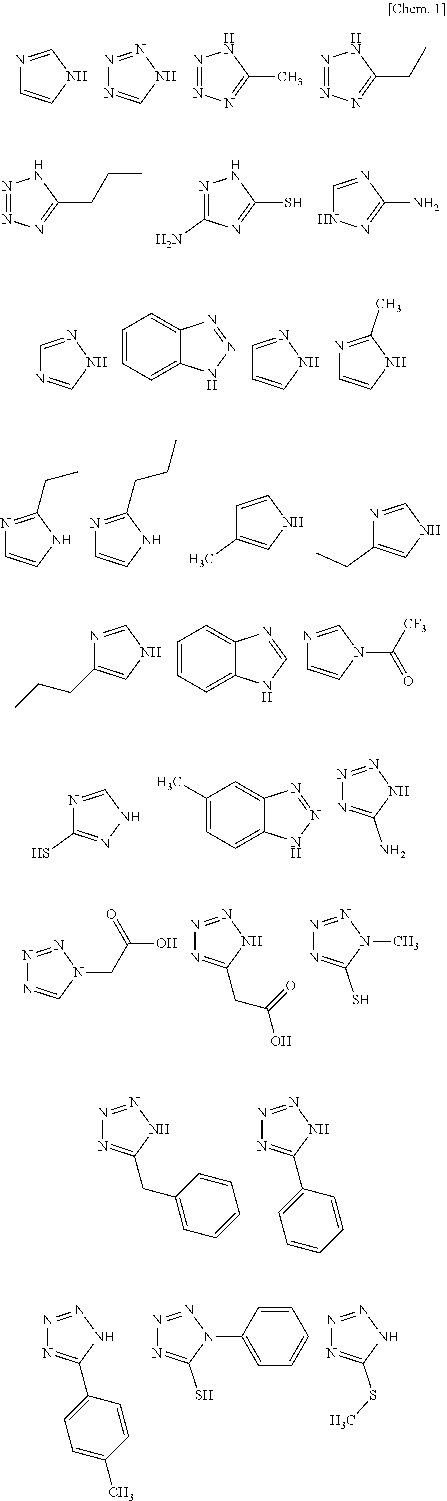

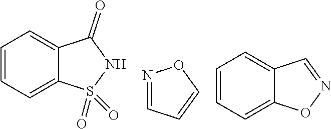

The amount of the nitrogen-containing heterocyclic compound added in the surface treatment liquid is preferably 0.1 mol % or more and 20 molo or less, more preferably 0.2 mol % or more and 10 mol % or less, and most preferably 0.5 mol % or more and 5 mol % or less with respect to the number of moles of the silylating agent.

### [Surface Treatment Method]

As described above, the surface of a semiconductor substrate is treated by contacting the surface of the semiconductor substrate with the surface treatment liquid containing the silylating agent described above.

The way of contacting the surface treatment liquid described above with the surface of the semiconductor substrate is exemplified by a spraying procedure, a spin coating procedure, and an immersion procedure. The surface treatment time is not limited, and may be, for example, 1 second or more and 60 seconds or less. The contact angle of water on the surface of the surface-treated semiconductor substrate is preferably 80 degrees or more and 120 degrees or less, and more preferably 82 degrees or more and 105 degrees or less.

### <Drying Step>

In the drying step, the semiconductor substrate after the contact with the surface treatment liquid is dried. The semiconductor substrate wetted with the surface treatment liquid may be cleaned with a rinse liquid before drying the semiconductor substrate. Alcohols such as methanol, ethanol, and isopropanol are preferred as the rinse liquid in light of their ability to remove the surface treatment liquid and their tendency of quick drying, or the like.

The way of drying the semiconductor substrate is not limited. Examples of the way of drying the semiconductor substrate include: heating the semiconductor substrate under atmospheric pressure; placing the semiconductor substrate under reduced-pressure atmosphere; heating the semiconductor substrate under reduced-pressure atmosphere; blowing an inert gas such as a nitrogen gas onto the semiconductor substrate; and leaving the semiconductor substrate to stand at room temperature; and the like.

### <Semiconductor Substrate Processing Step>

In the semiconductor substrate processing step, the semiconductor substrate is processed after a lapse of 6 hours or more from the completion of the drying of the semiconductor substrate. In addition, in the semiconductor substrate processing step, a percentage change in water contact angle is 20% or less, preferably 10% or less, and more preferably 5% or less, in which the percentage change in the water contact angle is calculated from the contact angle CA1 of water on the surface of the semiconductor substrate before the contact with the surface treatment liquid and the contact angle CA2 of water on the surface of the semiconductor substrate at the time of the processing of the semiconductor substrate according to the following equation: percentage change in water contact angle (%)=|(CA1−CA2)|/CA1×100

The present inventors have found that when a semiconductor substrate is surface-treated with the surface treatment liquid containing the silylating agent, the surface treatment effect is not significantly impaired over a long period of 6 hours or more. It is preferable that the semiconductor substrate is processed preferably after a lapse of 6 hours or more and 24 hours or less from the completion of the drying of the semiconductor substrate.

Preferably, the processing of the semiconductor substrate performed after the drying of the semiconductor substrate is patterning of a resist film, etching, ashing, film formation, thermal treatment, or impurity doping.

As described above, the present inventors provide the following items [1] to [5].
[1] A method for processing a semiconductor substrate, the method including:
treating a surface of a semiconductor substrate by contacting the surface with a surface treatment liquid containing a silylating agent, drying the semiconductor substrate after the contact with the surface treatment liquid, and
processing the semiconductor substrate after a lapse of 6 hours or more from the completion of the drying of the semiconductor substrate, in which
a percentage change in water contact angle is 20% or less, in which the percentage change in the water contact angle is calculated from a contact angle CA1 of water on the surface of the semiconductor substrate before the contact with the surface treatment liquid and a contact angle CA2 of water on the surface of the semiconductor substrate at the time of the processing of the semiconductor substrate according to the following equation:

percentage change in water contact angle (%)=|(CA1−CA2)|/CA1×100
[2] The method for processing a semiconductor substrate according to [1], including processing the semiconductor substrate after a lapse of 6 hours or more and 24 hours or less from the completion of the drying of the semiconductor substrate.
[3] The method for processing a semiconductor substrate according to [1] or [2], in which the material of the surface of the semiconductor substrate includes a silicon-containing material.
[4] The method for processing a semiconductor substrate according to [3], in which the silicon-containing material is at least one selected from the group consisting of silicon, SiO₂, SiN, SiOC, SiOCN, and Poly-Si.
[5] The method for processing a semiconductor substrate according to any one of [1] to [4], in which the silylating agent includes a compound represented by the following formula (1):

(R¹)₃Si—N(R²)(R³) (1)
in which in the formula (1), R¹ is a hydrogen atom, a halogen atom, or an organic group, in which a plurality of R¹s may be the same as or different from each other, R² is a hydrogen atom or a chain hydrocarbon group, R³ is a hydrogen atom, a chain hydrocarbon group, or a non-aromatic cyclic group, in which R² and R³ may be bonded to each other to form a ring,
and/or
a compound represented by the following formula (2):

(R¹)₃Si—N(R⁴)—Si(R⁵)₃ (2)
in which in the formula (2), R¹ is the same as R¹ in the formula (1), R⁴ is a hydrogen atom, a methyl group, a trimethylsilyl group, or a dimethylsilyl group, R⁵ is a hydrogen atom or an organic group, and a plurality of R⁵s may be the same as or different from each other, and the sum of the number of carbon atoms in three R⁵s is 1 or more.
[6] The method for processing a semiconductor substrate according to any one of [1] to [5], in which the processing of the semiconductor substrate performed after the drying of the semiconductor substrate is patterning of a resist film, etching, ashing, film formation, thermal treatment, or impurity doping.

### EXAMPLES

Hereinafter, the present invention will be described in detail with reference to Examples. The scope of the present invention is not limited to these Examples.

### [Cleaning of Surface of Semiconductor Substrate]

A silicon substrate having silicon exposed on its surface (Si substrate), a silicon substrate having a SiO₂ film formed using triethoxysilane on its surface (SiO₂ substrate), and a silicon substrate having a layer made of SiN on its surface (SiN substrate) were used as a semiconductor substrate. These semiconductor substrates were cleaned according to the following Pre-T1 treatment method or Pre-T2 treatment method.

### (Pre-T1 Treatment Method)

The semiconductor substrate was immersed in hydrofluoric acid (49 wt % aqueous hydrofluoric acid solution:water=1:100 (volume ratio)) at 25° C. for 1 minute. Then, the semiconductor substrate was rinsed with deionized water and dried by nitrogen blowing. Further, the dried semiconductor substrate was immersed in APM, which was prepared by mixing hydrogen peroxide, aqueous ammonia, and ultrapure water at a volume ratio of =1:1:5, at 25° C. for 1 minute. Thereafter, the semiconductor substrate was rinsed with deionized water and dried by nitrogen blowing. This cleaning treatment method is referred to as Pre-T1.

The semiconductor substrate was immersed in APM, which was prepared by mixing hydrogen peroxide, aqueous ammonia, and ultrapure water at a volume ratio of 1:1:5, at 25° C. for 1 minute. Then, the semiconductor substrate was rinsed with deionized water and dried by nitrogen blowing. Further, the dried semiconductor substrate was immersed in hydrofluoric acid (49 wt % aqueous hydrofluoric acid solution:water=1:100 (volume ratio)) at 25° C. for 1 minute. Thereafter, the semiconductor substrate was rinsed with deionized water and dried by nitrogen blowing. This cleaning treatment method is referred to as Pre-T2.

### Examples 1 to 3

Each semiconductor substrate cleaned according to the Pre-T1 treatment method was immersed in a solution of hexamethyldisilazane (HMDS) and imidazole (Imd) in propylene glycol monomethyl ether acetate as a surface treatment liquid at 25° C. for 20 seconds. The concentration of hexamethyldisilazane in the surface treatment liquid was 10% by mass. The concentration of imidazole in the surface treatment liquid was 4.2% by mass. After the immersion, the semiconductor substrate was rinsed with isopropyl alcohol (IPA), and dried by nitrogen blowing.

### Examples 4 to 6

The surface treatment of a semiconductor substrate was carried out in the same manner as in Examples 1 to 3 except that the surface treatment liquid was replaced with a solution of N,N-dimethylaminotrimethylsilane (TMSDMA) in propylene glycol monomethyl ether acetate. The concentration of N,N-dimethylaminotrimethylsilane in the surface treatment liquid was 7.8% by mass.

### Examples 7 to 9

The surface treatment of a semiconductor substrate was carried out in the same manner as in Examples 1 to 3 except that the Pre-T1 treatment method was changed to the Pre-T2 treatment method.

### Examples 10 to 12

The surface treatment of a semiconductor substrate was carried out in the same manner as in Examples 4 to 6 except that the Pre-T1 treatment method was changed to the Pre-T2 treatment method.

### Comparative Examples 1 to 6

The contact angle of water on the surface of a semiconductor substrate was measured in the same manner as in Examples 1 to 3 and Examples 7 to 9 except that any treatment on the surface of the semiconductor substrate was not carried out.

### (Measurement of Contact Angle of Water)

Each semiconductor substrate after the surface treatment was stored under the conditions of 20° C. and 45% humidity, and the contact angle of water on the surface of the semiconductor substrate was measured for each elapsed time listed in Table 1. The contact angle of water was measured using Dropmaster 700 (manufactured by Kyowa Interface Science Co., LTD.) 2 seconds after dropping of pure water (2.0 μL) on the surface of the substrate. The results are shown in Table 1. Further, the contact angle of water on the surface of the semiconductor substrate before the contact with the surface treatment liquid was designated as CAL and the contact angle of water on the surface of the semiconductor substrate at each elapsed time was designated as CA2, and a percentage change in water contact angle was calculated according to the following equation. The calculated percentage change in the water contact angle is shown in Table 2.

percentage change in water contact angle (%)=|(CA1−CA2)|/CA1×100

TABLE 1

| | | | Surface | Contact angle of water after each elapsed time from | | | | | | |
|---|---|---|---|---|---|---|---|---|---|---|
| | | Treatment | treatment | drying of semiconductor substrate (degree) | | | | | | |
| | Substrate | method | liquid | 0 hr | 1 hr | 2 hr | 3 hr | 6 hr | 12 hr | 24 hr |
| Example 1 | Si | Pre-T1 | HMDS/Imd | 83.0 | 81.8 | 81.9 | 81.7 | 80.7 | 80.6 | 80.1 |
| Example 2 | SiO₂ | | | 99.9 | 99.5 | 100 | 99.7 | 99.4 | 99.5 | 99.7 |
| Example 3 | SIN | | | 78.9 | 78.1 | 77.5 | 77.4 | 76.6 | 75.4 | 73.6 |
| Example 4 | Si | | TMSDMA | 83.5 | 83.2 | 82.7 | 82.8 | 83.8 | 83.0 | 82.3 |
| Example 5 | SiO₂ | | | 75.5 | 76.2 | 75.9 | 76.7 | 75.9 | 75.7 | 75.2 |
| Example 6 | SIN | | | 52.2 | 52.0 | 53.4 | 53.2 | 52.8 | 55.6 | 57.1 |
| Example 7 | Si | Pre-T2 | HMDS/Imd | 90.6 | 88.8 | 89.5 | 88.0 | 86.3 | 84.8 | 80.7 |
| Example 8 | SiO₂ | | | 100.4 | 99.6 | 99.2 | 99.4 | 99.0 | 99.0 | 98.7 |
| Example 9 | SiN | | | 75.0 | 74.3 | 73.9 | 73.8 | 71.3 | 71.1 | 71.1 |
| Example 10 | Si | | TMSDMA | 95.2 | 94.5 | 94.5 | 94 | 92.9 | 88.5 | 85.4 |
| Example 11 | SiO₂ | | | 82.3 | 80.6 | 80.0 | 79.8 | 79.7 | 79.9 | 80.7 |
| Example 12 | SiN | | | 57.4 | 56.1 | 55.6 | 55.4 | 55.9 | 56.5 | 58.2 |
| Comparative | Si | Pre-T1 | — | 7.4 | 7.6 | 8.1 | 7.5 | 13.2 | 20.3 | 26.9 |
| Example 1 | | | | | | | | | | |
| Comparative | SiO₂ | | | 7.1 | 7.2 | 7.3 | 7.2 | 10.2 | 13.5 | 15.5 |
| Example 2 | | | | | | | | | | |
| Comparative | SIN | | | 7.3 | 8.8 | 12.0 | 14.7 | 21.3 | 27.4 | 30.7 |
| Example 3 | | | | | | | | | | |
| Comparative | Si | Pre-T2 | | 83.1 | 77.3 | 74.7 | 72.1 | 66.3 | 63.4 | 58.4 |
| Example 4 | | | | | | | | | | |
| Comparative | SiO₂ | | | 6.5 | 13.4 | 10.5 | 16.8 | 17.0 | 17.5 | 20.1 |
| Example 5 | | | | | | | | | | |
| Comparative | SIN | | | 6.6 | 14.6 | 19.4 | 22.6 | 23.7 | 30.4 | 34.3 |
| Example 6 | | | | | | | | | | |

TABLE 2

| | | | Surface | Percentage change in water contact angle after each | | | | | | |
|---|---|---|---|---|---|---|---|---|---|---|
| | | Treatment | treatment | elapsed time from drying of semiconductor substrate (%) | | | | | | |
| | Substrate | method | liquid | 0 hr | 1 hr | 2 hr | 3 hr | 6 hr | 12 hr | 24 hr |
| Example 1 | Si | Pre-T1 | HMDS/Imd | 0.0 | 1.4 | 1.3 | 1.6 | 2.8 | 2.9 | 3.5 |
| Example 2 | SiO₂ | | | 0.0 | 0.4 | 0.1 | 0.2 | 0.5 | 0.4 | 0.2 |
| Example 3 | SIN | | | 0.0 | 1.0 | 1.8 | 1.9 | 2.9 | 4.4 | 6.7 |
| Example 4 | Si | | TMSDMA | 0.0 | 0.4 | 1.0 | 0.8 | 0.4 | 0.6 | 1.4 |
| Example 5 | SiO₂ | | | 0.0 | 0.9 | 0.5 | 1.6 | 0.5 | 0.3 | 0.4 |
| Example 6 | SIN | | | 0.0 | 0.4 | 2.3 | 1.9 | 1.1 | 6.5 | 9.4 |
| Example 7 | Si | Pre-T2 | HMDS/Imd | 0.0 | 2.0 | 1.2 | 2.9 | 4.7 | 6.4 | 10.9 |
| Example 8 | SiO₂ | | | 0.0 | 0.8 | 1.2 | 1.0 | 1.4 | 1.4 | 1.7 |
| Example 9 | SIN | | | 0.0 | 0.9 | 1.5 | 1.6 | 4.9 | 5.2 | 5.2 |
| Example 0 | Si | | TMSDMA | 0.0 | 0.7 | 0.7 | 1.3 | 2.4 | 7.0 | 10.3 |
| Example 11 | SiO₂ | | | 0.0 | 2.1 | 2.8 | 3.0 | 3.2 | 2.9 | 1.9 |
| Example 12 | SIN | | | 0.0 | 2.3 | 3.1 | 3.5 | 2.6 | 1.6 | 1.4 |
| Comparative | Si | Pre-T1 | — | 0.0 | 2.7 | 9.5 | 1.4 | 78.4 | 174.3 | 263.5 |
| Example 1 | | | | | | | | | | |
| Comparative | SiO₂ | | | 0.0 | 1.4 | 2.8 | 1.4 | 43.7 | 90.1 | 118.3 |
| Example 2 | | | | | | | | | | |
| Comparative | SIN | | | 0.0 | 20.5 | 64.4 | 101.4 | 191.8 | 275.3 | 320.5 |
| Example 3 | | | | | | | | | | |
| Comparative | Si | Pre-T2 | | 0.0 | 7.0 | 10.1 | 13.2 | 20.2 | 23.7 | 29.7 |
| Example 4 | | | | | | | | | | |
| Comparative | SiO₂ | | | 0.0 | 106.2 | 61.5 | 158.5 | 161.5 | 169.2 | 209.2 |
| Example 5 | | | | 0.0 | 121.2 | 193.9 | 242.4 | 259.1 | 360.6 | 419.7 |

As can be seen from Tables 1 and 2, according to the method including: treating the surface of a semiconductor substrate by contacting the surface with a surface treatment liquid containing a silylating agent; drying the semiconductor substrate after the contact with the surface treatment liquid; and processing the semiconductor substrate after a lapse of 6 hours or more from the completion of the drying of the semiconductor substrate, the percentage change in the water contact angle specified above can be maintained at a low value for a long period of time. In other words, the method according to Examples provides a method for processing a semiconductor substrate, which method suppresses a change in the condition of the surface of the semiconductor substrate over a long period of time and additionally enables favorable processing of the semiconductor substrate.

What is claimed is:

1. A method for processing a semiconductor substrate, the method comprising:
treating a surface of the semiconductor substrate by contacting the surface with a surface treatment liquid comprising a silylating agent;
drying the semiconductor substrate after the contact with the surface treatment liquid; and
processing the semiconductor substrate after a lapse of 6 hours or more from completion of the drying of the semiconductor substrate, wherein
a percentage change in water contact angle is 20% or less, wherein the percentage change in the water contact angle is calculated from a contact angle CA1 of water on the surface of the semiconductor substrate before the contact with the surface treatment liquid and a contact angle CA2 of water on the surface of the semiconductor substrate at a time of the processing of the semiconductor substrate according to an equation:
percentage change in water contact angle (%)=|(CA1−CA2)|/CA1×100

2. The method for processing a semiconductor substrate according to claim 1, comprising processing the semiconductor substrate after a lapse of 6 hours or more and 24 hours or less from the completion of the drying of the semiconductor substrate.

3. The method for processing a semiconductor substrate according to claim 1, wherein a material of the surface of the semiconductor substrate comprises a silicon-containing material.

4. The method for processing a semiconductor substrate according to claim 3, wherein the silicon-containing material is at least one selected from the group consisting of silicon, SiO₂, SiN, SiOC, SiOCN, and Poly-Si.

5. The method for processing a semiconductor substrate according to claim 1, wherein the silylating agent comprises a compound represented by formula (1):
(R¹)₃Si—N(R²)(R³) (1)
wherein in the formula (1), R¹ is a hydrogen atom, a halogen atom, or an organic group, and a plurality of R¹s are the same as or different from each other, R² is a hydrogen atom or a chain hydrocarbon group, R³ is a hydrogen atom, a chain hydrocarbon group, or a non-aromatic cyclic group, and R² and R³ are optionally bonded to each other to form a ring,
and/or
a compound represented by formula (2):
(R¹)₃Si—N(R⁴)—Si(R⁵)₃ (2)
wherein in the formula (2), R¹ is the same as RI in the formula (1), R⁴ is a hydrogen atom, a methyl group, a trimethylsilyl group, or a dimethylsilyl group, R⁵ is a hydrogen atom or an organic group, and a plurality of R⁵s are the same as or different from each other, and a sum of number of carbon atoms in three R⁵s is 1 or more.

6. The method for processing a semiconductor substrate according to claim 1, wherein the processing of the semiconductor substrate performed after the drying of the semiconductor substrate is patterning of a resist film, etching, ashing, film formation, thermal treatment, or impurity doping.
